(19) United States
(12) Patent Application Publication
(10) Pub. No.: US 2006/0187638 A1
(43) Pub. Date: Aug. 24, 2006

(54) System and method for liquid cooling of an electronic device

(76) Inventors: Wade D. Vinson, Magnolia, TX (US); Kenneth Ray Baker, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/065,992

(22) Filed: Feb. 24, 2005

(51) Int. Cl. H05K 7/20

(52) U.S. Cl. 361/698

(57) ABSTRACT

In certain embodiments, a system and method for liquid cooling of an electronic device, including a heat exchanger disposed adjacent an electronic component within a housing of the electronic device and adapted to remove heat from the electronic component. The liquid cooling system utilizes a support mounted adjacent an expansion slot of the electronic device. The support is configured to route liquid coolant to the heat exchanger.

### BACKGROUND

This section is intended to introduce the reader to various aspects of art, which may be related to various aspects of the present invention that are described or claimed below. This discussion is believed to be helpful in providing the reader with background information to facilitate a better understanding of the various aspects of the present invention. Accordingly, it should be understood that these statements are to be read in this light, and not as admissions of prior art.

Certain components of electronic devices generate a significant amount of heat, which should be removed to ensure proper operation of the electronic device. For example, a central processing unit (CPU) of a computer generates considerable heat. Consequently, various cooling techniques have been developed to remove heat produced within an electronic device. Such techniques may employ fans, blowers, heat sinks, heat pipes, vapor chambers, and other heat transfer devices to maintain acceptable operating temperatures of the electrical components housed within the device. Unfortunately, these heat transfer devices are becoming less effective at cooling electronic components such as processors, which are progressively generating more heat with technological improvements (e.g., faster processing speeds).

### BRIEF DESCRIPTION OF THE DRAWINGS

FIG. 1 is a side view of an electronic device employing a liquid cooling system and utilizing an expansion slot to facilitate installation and operation of the liquid cooling system in accordance with embodiments of the present invention;

FIG. 2 illustrates one configuration of the liquid cooling system from a top sectional view A-A of the electronic device of FIG. 1 in accordance with embodiments of the present invention;

FIG. 3 illustrates another configuration of the liquid cooling system from the top sectional view A-A of the electronic device of FIG. 1 in accordance with embodiments of the present invention;

FIG. 4 is a perspective view of a faceplate for an expansion slot, wherein the faceplate is configured to facilitate coupling of parts of a liquid cooling system internal and external relative to an electronic device in accordance with embodiments of the present invention;

FIG. 5 is a perspective view of an expansion card adapted to facilitate installation and operation of a liquid cooling system to cool an electrical component within an electronic device in accordance with embodiments of the present invention;

FIG. 6 is a perspective view of an expansion card adapted to facilitate self-contained liquid cooling of an electrical component in an electrical device in accordance with embodiments of the present invention;

FIG. 7 is a block diagram of a method of cooling an electrical component within an electronic device in accordance with embodiments of the present invention; and

FIG. 8 is a side view of a rack system having a plurality of rack electronic devices each adapted to facilitate liquid cooling of electrical components via their respective expansion slots in accordance with embodiments of the present invention.

### DETAILED DESCRIPTION OF SPECIFIC EMBODIMENTS

One or more exemplary embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

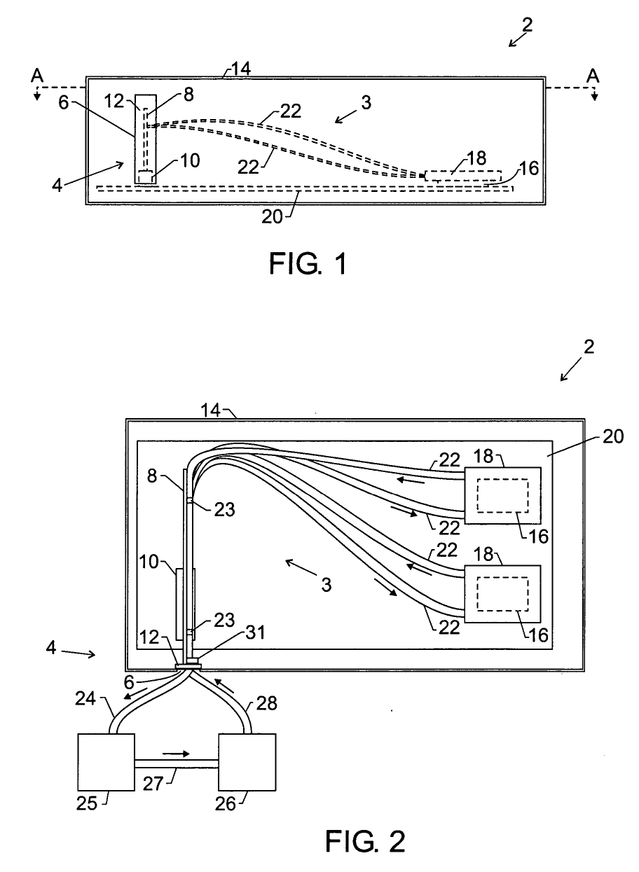

FIG. 1 is a side view of an electronic device 2 having an expansion slot 4 accommodating a liquid cooling system 3 in accordance with embodiments of the present invention. As discussed below, the expansion slot 4 may be adapted to facilitate liquid cooling of components of the electronic device 2. The liquid cooling may be implemented without significant modifications, such as without the cutting or modifying of the housing of the electronic device 2, to accommodate coolant conduits and other components.

In certain embodiments, the expansion slot 4 may include an access opening 6, or an expansion card 8, or a connector 10, or a faceplate 12 or a region in the vicinity of these components, or any combination thereof. The illustrated embodiment includes all of these elements. The faceplate 12 may be part of the card 8 (i.e., the faceplate may couple to the board of the card 8) or the faceplate 12 may be separate from the card 8. With or without the card 8, the faceplate 12 may reside on the access opening 6 of the expansion slot 4. The access opening 6 and surrounding portion of the housing 14 may include coupling elements which mate with mechanical connectors on the faceplate 12.

In general, electronic systems and devices, such as desktop computers and servers, often provide expansion capabilities such as the expansion slot 4 for expansion cards 8 and other components and devices, such as disk drives, hard drives, and so forth. In the case of expansion cards, the illustrated slot 4 may receive typical video cards, sound cards, modems, image capture cards, and so on, as well as cards configured to facilitate liquid cooling, as discussed below. Standards for such exemplary cards and connectors include, for example, Industry Standard Architecture (ISA), Extended or Extended Industry Standard Architecture (EISA), Micro Channel Architecture (MCA), Video Electronics Standard Association (VESA) standard, Peripheral Component Interconnect (PCI) standard, small computer system interface (SCSI) standard, Accelerated Graphics Port (AGP) standard, or variations thereof, and so forth. However, other expansion cards 8 and electrical communication connectors 10, such as card edge connectors, may be employed in certain embodiments.

Furthermore, the electronic device 2 may include a variety of electronic devices and components, such as processors, random access memory, hard drives, graphics processing modules, audio processing modules, removable media drives, input/output ports, and so forth. In certain embodiments, the electronic device 2 is a computer system, such as a desktop computer, a laptop computer, a tablet personal computer, or a rack mount computer. By further example, the electronic device 2 may be a server, such as a floor mount or a rack mount server.

As illustrated in FIG. 1, the expansion slot 4 facilitates liquid cooling of an electronic component 16 (e.g., processor, memory, etc.) within the housing 14 of the device 2. In certain embodiments, the expansion slot 4 may facilitate supply of liquid coolant to a cooling element (e.g., heat exchanger 18) that removes heat from the electronic component 16 and/or other electronic components. It should be noted that a traditional functional (e.g., video, sound, etc.) capability of an expansion card 8 may be utilized in conjunction with certain embodiments that employ the expansion card 8 to facilitate coolant supply to a cooling element, such as the heat exchanger 18. In the illustrated embodiment, the expansion card 8 inserts through the access opening 6, an open cover area, or another access region, thereby facilitating coupling of the expansion card 8 to the connector 10 of the expansion slot 4. The connector 10 may be disposed on a printed circuit board 20 (e.g., motherboard, backplane, and so forth) within the electronic device 2. Thus, within the housing 14, the card connector 10 of the expansion slot 4 may couple circuitry and other electronic components of the expansion card 8 to the circuit board 20. Lastly, the faceplate 12 may be installed on the access opening 6 situated on the housing 14 (wall) of the electronic device 2. In certain embodiments, the expansion slot 4 facilitates circulation of a liquid coolant via a pumping mechanism through conduits (e.g., conduits 22) and one or more heat exchangers (e.g., exchanger 18) disposed adjacent electronic components (e.g., component 16) within the electronic device 2 (e.g., computers, servers, rack servers, etc.). Alternatively, the heat differentials in the liquid cooling system 3 may cause circulation of the liquid coolant without a pumping mechanism In operation, the liquid cooling system 3 transfers heat from the electronic component 16 to the liquid coolant flowing through the one or more heat exchangers (e.g., exchanger 18). In turn, the liquid cooling system 3 removes this absorbed heat from the liquid coolant away from the electronic component 16. The liquid cooling system 3 then returns or recirculates the liquid coolant back to the electronic component 16 for further heat removal.

Moreover, as indicated, cooling system parts or elements are disposed inside the housing 14, while some parts of the liquid cooling system 3 may be optionally outside the housing 14. In other words, exemplary embodiments of the liquid cooling system 3 may have sections residing external to the electronic device 2, or the cooling system 3 may be self-contained within the electronic device 2. In either case, the liquid cooling system 3 utilizes the expansion slot 4 of the electronic device 2. It should be noted that throughout the discussion, “internal” generally refers to inside the housing 14 of the electronic device 2, and “external” generally refers to outside of the housing 14 of the electronic device 2. Similarly, the phrase “self-contained” generally refers to liquid cooling equipment or the liquid cooling system 3 contained within the housing 14 of the electronic device 2.

For the example of a liquid cooling system having parts external to the electronic device 2, a coolant conduit (e.g., tubing) may be routed through an expansion-slot access opening (e.g., opening 6) in the housing 14 of the electronic device 2. To better secure the conduit, a structure (e.g., faceplate 12) having a fitting for receiving the coolant conduit may be situated on the access opening 6 of the expansion slot 4. In addition, the structure may include an expansion card (e.g., card 8) having the faceplate 12 with the conduit fitting. As indicated, the expansion card 8 may be inserted into opening 6 of the expansion slot 4 and coupled to a connector (e.g., connector 10) of the expansion slot 4. If an expansion card 8 is employed, the coolant conduit (e.g., conduit 22) may be advantageously secured to the board of the expansion card 8. Additional cooling system parts may also be coupled or mounted to the board of the expansion card 8. For example, all parts of an exemplary liquid cooling system may be disposed within the electronic device 2 to provide for self-contained liquid cooling. Moreover, some or all of the cooling system parts may mount to the expansion card 8 (e.g., without a conduit fitting in the faceplate 12). In sum, there are a variety of ways in which a typical or special expansion slot 4 of an electronic device 2 may be used to facilitate liquid cooling of the electronic device 2.

As mentioned above, exemplary embodiments of the liquid cooling system 3 include a cooling element, such as the process heat exchanger 18, mounted adjacent (e.g., in contact or in thermal communication with) the electronic component 16. This cooling element or heat exchanger 18 receives a liquid coolant to remove heat from the electronic component 16. Exemplary process heat exchangers 18 include liquid blocks, cold plates, microchannel heat collectors, and the like. It should be emphasized, however, that other cooling elements and exemplary heat exchangers 18 may be utilized in the liquid cooling system 3. For example, other cooling elements include liquid spray systems, evaporators, thermo-siphon devices, shell-and-tube heat exchangers, radiators, cooling coils, and so forth. Further, the cooling element or heat exchanger 18 at the electronic component 16 (e.g., CPU) may be a heat pipe, loop thermosiphon or vapor chamber, or a cooling element having such features, which may eliminate the need for a pump in the coolant circuit by providing two-phase and/or capillary action to move the cooling fluid, for example. It should be emphasized that any number and variety of cooling elements and process heat exchangers 18 may be utilized to cool an electronic device 2 via an expansion slot 4 including the expansion card 8.

In one embodiment, the heat exchanger 18 is a liquid block, which is a mass of metal (e.g., a block of copper, aluminum, etc.) with channels (e.g., tubular) for a liquid coolant or cooling medium such as water to pass through. Heat may be absorbed through the metal mass and carried away by the cooling medium running through the block. In conjunction with the liquid block, exemplary water cooling systems may use a pump, tubing, storage tank, radiator, and so forth, disposed along the liquid coolant circuit. For a heat exchanger 18 that is a cold plate, the cold plate may have features similar to those of the liquid block. Moreover, a cold plate may be associated with a solid state thermoelectric device, such as a peltier device (e.g., peltier effect module). The cold plate also may include a heat pipe, a vapor chamber, or other elements in a generally flat plate. The process heat exchanger 18 similarly be a microchannel heat collector which may have features of a cold plate and includes fine channels etched into a relatively small piece of material (e.g., silicon). The channels may carry a cooling medium, such as water or another fluid that absorbs heat generated by the electronic component 16. As with cooling systems for the similar liquid blocks and cold plates, the cooling medium exiting the microchannel heat collector may pass through one or more heat exchangers and conduits, such that heat can be removed from the cooling medium. For example, the cooling medium may pass through a radiator where heat is transferred to the air. After being cooled, the cooling medium is circulated back to the microchannel heat collector adjacent to the electronic component 16.

In operation, a coolant pumping mechanism may be employed to pump the cooling medium between the process heat exchanger 18 and remote cooling mechanisms, e.g., radiator, utility heat exchanger, etc. In certain examples, the cooling system forms a circulating coolant loop, circuit, etc. Exemplary pumps include an electrokinetic pump (such as provided by Cooligy, Inc. of Mountain View, Calif.), a Lorentz magnetic liquid metal pump (such as provided by from NanoCoolers of Austin, Tex.), a positive displacement pump (e.g., diaphragm pump), a centrifugal pump, or another pumping mechanism.

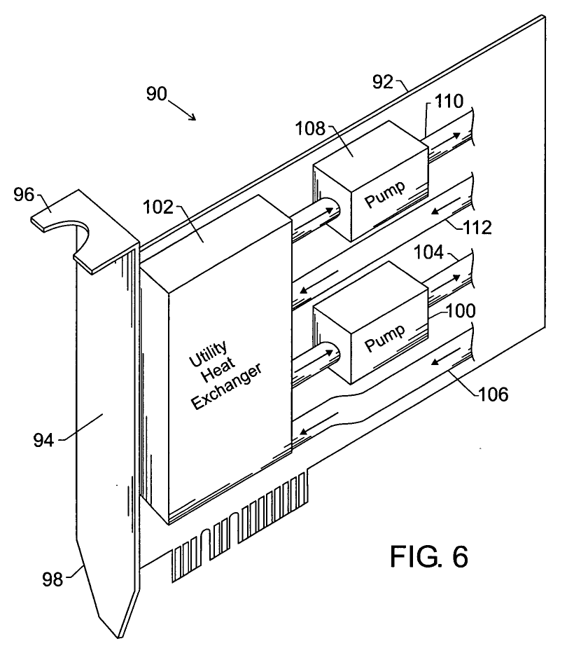

As discussed above, a coolant pumping mechanism of the liquid cooling system 3 may be disposed external or internal to the housing 14. If external, the pumping mechanism may circulate liquid coolant into and from the housing 14 through a faceplate 12 installed on the access opening 6 of the expansion slot 4. The faceplate 12 may reside on the access opening 6 with or without an expansion card 8. In operation, the liquid coolant flows through the faceplate 12 and then through a conduit 22 to the process heat exchanger 18. If internal, the coolant pumping mechanism is disposed inside the housing 14 of the electronic device 2 and still may deliver liquid coolant to the exchanger 18 via conduit 22. Such an internal pumping mechanism may be mounted on a board (see FIG. 6) of an expansion card 8 inserted into the access opening 6 of the expansion slot 4. Conversely, an internal pumping mechanism may also be disposed elsewhere inside the housing 14. Whether the pumping mechanism is internal or external to the housing 14, liquid coolant generally flows through a conduit 22 to the heat exchanger 18.

Furthermore, for a circulating coolant system, a second conduit 22 may return coolant to the pump and/or to a downstream utility heat exchanger adapted to remove heat absorbed by the returned liquid coolant. This utility heat exchanger may reside internal or external to the housing 14. Exemplary utility heat exchangers include a radiator, piping coils, tubing coils, a shell-and-tube heat exchanger, and so on.

FIG. 2 is a top sectional view of the electronic device of FIG. 1 sectioned through line A-A. One or more conduits 22, such as rigid or flexible tubing, piping, and the like, circulate liquid coolant through a cooling element, such as the process heat exchanger 18. In this example, conduits 22 may also circulate liquid coolant to other cooling elements, such as another process heat exchanger 18 which removes heat from electrical components, such as another component 16. Thus, conduits 22 may provide for coolant supply and coolant return from two or more heat exchangers 18 of the same or different type. Furthermore, the conduits 22 may be secured to the card 8 via fastening elements 23, for example. Lastly, in this example, a single return conduit 24 and a single supply conduit 28 are coupled to the four conduits 22 via a conduit manifold 31.

In the illustrated embodiment, heated coolant exiting the process heat exchangers 18 circulate within a subsystem external to the housing 14. The subsystem processes the liquid coolant (e.g., removes heat from the coolant). Such an external cooling subsystem may include a return conduit 24, a circulating pump 25, a utility heat exchanger 26 (e.g., radiator, coils, etc.), a conduit 27, and a supply conduit 28. Alternatively, or in addition, a subsystem (not illustrated) internal to the housing 14 may remove heat from the liquid coolant. As indicated, external and internal systems may include a coolant pumping mechanism (e.g., pump 25) that pressurizes and circulates the liquid coolant through the coolant fluid circuit.

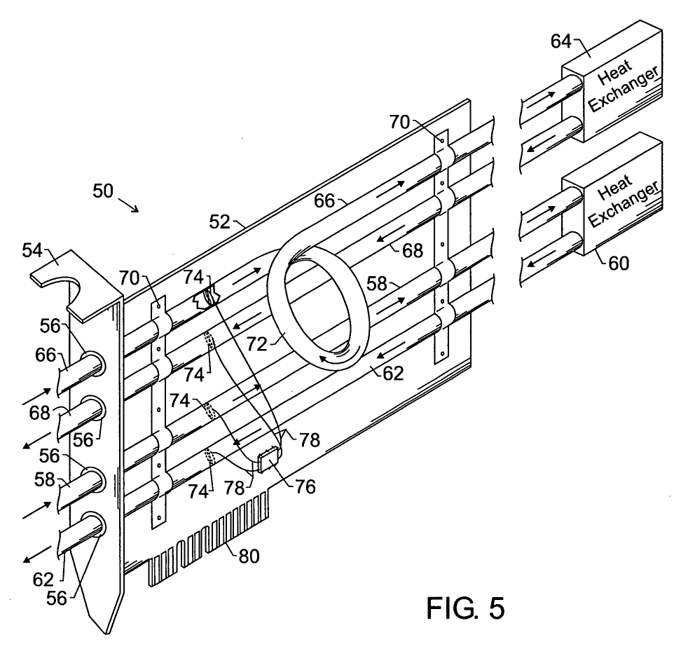

In sum, an expansion card 8 having a faceplate 12 may be inserted into the access opening 6, such that the expansion card 8 can couple to the connector 10 of the expansion slot 4. The coolant conduits, such as portions of supply and return coolant conduits 22, may route through the faceplate 12 and mount to a plain board or circuit board of the expansion card 8 via fastening elements 23, for example (see also FIG. 5). As discussed below, the expansion card 8 may also include sensors and/or make use of integrated electronics in the monitoring of the liquid cooling system.

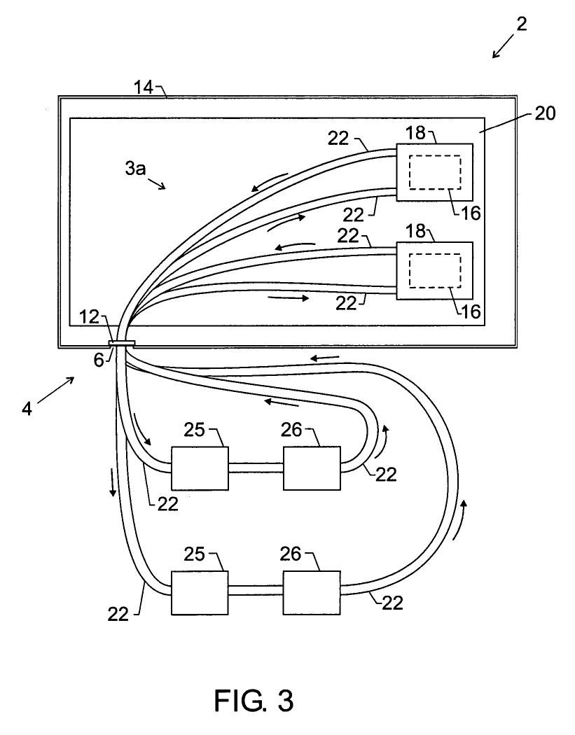

FIG. 3 is a top sectional view of the electronic device of FIG. 1 through line A-A. The depicted cooling system 3a utilizes a faceplate 12 without an expansion card 8. In the illustrated embodiment, the faceplate 12 has conduit holes or fittings that couple different parts of the liquid cooling system 3a inside and outside of the housing 14. The faceplate 12 provides a pathway for routing of conduits and the flow of liquid coolant into the interior of the housing 14 without having to cut or modify the housing 14. Thus, in operation, liquid coolant may be circulated from an external source through the faceplate 12 (situated on the access opening 6 of expansion slot 4) and into the housing 14. One or more coolant conduits 22 may be routed through the faceplate 12. The illustrated external portion of the liquid cooling system 3a includes one or more return and supply conduits 22, as well as one or more pumps 25 and utility heat exchangers 26. The pumps 25 circulate the liquid coolant through the conduits 22. The utility heat exchangers 26 remove heat from the liquid coolant.

In certain embodiments, the liquid cooling systems 3a may be self-contained within the housing 14 of the electronic device 2 without coupling to elements external to the housing 14. For instance (see FIG. 6), as discussed below, a coolant pump, a utility heat exchanger, and portions of conduits 22 may all be disposed inside the housing 14. Further, these cooling system elements may mount to an expansion card 8 inserted into the expansion slot 4. The card-mounted equipment may supply and receive liquid coolant from the illustrated process heat exchangers 18 within the electronic device 2. For example, supply conduits 22 may transport liquid coolant from the discharge of the pumping mechanism mounted on the expansion card 8 or board to the process heat exchangers 18 (disposed adjacent the electronic components 16). Further, return conduits 22 may transport the heated liquid coolant exiting the process heat exchangers 18 to one or more utility heat exchangers (not illustrated) mounted on the card 8 or a board (or elsewhere inside the housing 14) where heat is removed from the liquid coolant. A return conduit may also transport the processed liquid coolant from the discharge of the utility heat exchanger to the suction of the pumping mechanism, for example. This return conduit may also mount to the board of the expansion card 8.

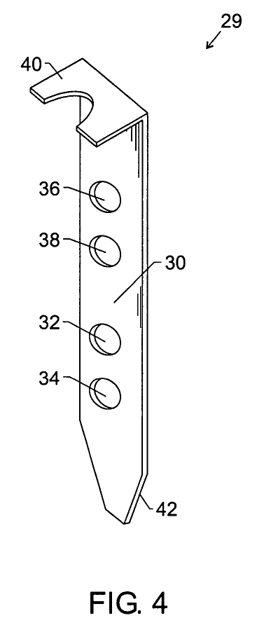

FIG. 4 is a perspective view of a faceplate 29 of an expansion slot of an electronic device (e.g., electronic device 2 of FIG. 1). The faceplate 29 may be configured to aid in coupling of an internal part of a liquid cooling system residing inside the housing 14 of the electronic device 2 with an external part of the liquid cooling system residing outside of the housing 14. The body 30 of the faceplate 29 may include one or more fittings 32, 34, 36, and 38 which may simply be a hole or opening, or may include a variety of coupling elements, such as piping or tubing fittings, flanges, screwed connections, welded connections, dripless quick disconnects, blind mate fittings, and so on. The fittings 32, 34, 36, and 38 may be adapted to secure and/or provide a pathway for conduits that supply, circulate, and/or return a liquid coolant to and from internal cooling elements, such as heat exchangers (e.g., exchangers 18 of FIG. 1), disposed within the housing 14 of the electronic device 2.

For example, the fittings 32, 34, 36, and 38 may be configured to receive conduits into the housing which supply coolant from the discharge of an external coolant pump to an internal heat exchanger, such as the process heat exchangers 18. For instance, the fittings 32 and 34 may be adapted, respectively, to simplify coolant supply and return into the interior of the housing. The fittings 36 and 38 may be adapted for redundant and/or independent coolant-flow capability. It should be emphasized that the number, types, and arrangements of fittings on the faceplate 29 may vary depending on the liquid cooling system, the electronic device, and so forth.

The faceplate 29 may also include coupling elements 40 and 42 near or at the ends of the faceplate 29. These coupling elements 40 and 42 are adapted to secure the faceplate 29 to the expansion slot or expansion receptacle (access opening) disposed on an electronic device (e.g., computer, server, or other processor-based system). The coupling elements 40 and 42 may include a variety of configurations, such as those employed by standard or modified expansion cards, expansion boards, faceplates, and so forth. The coupling elements 40 and 42 are configured to mate with corresponding structural connectors disposed on the expansion slot (access opening) and/or housing.

FIG. 5 is a perspective view of an expansion card 50 adapted to simplify the installation and operation of a liquid cooling system. For example, the expansion card 50 can be used as the card 8 in the embodiments of FIGS. 1-3. Again, exemplary standards for expansion cards and slots include ISA, EISA, PCI, AGP, and so on. The expansion card 50 includes a board 52 coupled to a faceplate 54 having tubing fittings 56 adapted to expedite and/or make straightforward the supply and return of liquid coolant into an electronic device. The expansion card 50 may assist in circulation of liquid coolant and provide for ease of coupling to an external cooling system via an expansion slot. Referring to the embodiments of FIGS. 1-3, the expansion card 50, as indicated, may generally correlate to card 8, which mounts in the expansion slot 4, to promote circulation of liquid coolant with cooling elements, such as the heat exchanger 18, internal to the housing 14.

In general, a supply conduit 58 may be routed through a tubing fitting 56 from an external cooling system to transport cooled coolant to a heat exchanger 60 disposed internal to a housing of an electronic device. A conduit 62 may return heated coolant to the external system, for example. The faceplate 54 may also accommodate conduits for additional heat exchangers, such as a second heat exchanger 64. If so, the conduit 66 may transport cooled coolant into the second heat exchanger 64. A conduit 68 may transport and return heated coolant exiting the heat exchanger 64 to the external part of the liquid cooling system. The exemplary heat exchangers 60 and 64 (e.g., cold plates) are generally positioned in thermal communication with one or more electrical components to be cooled.

The conduits 58, 62, 66, and 68 may mount to the board 52 with clamps 70 or other fastening/support elements, and the like. The conduits 58, 62, 66, and 68 may also include a service loop, such as service loop 72, to provide additional length or slack of conduit to promote ease of installation and attachment of the conduits to the liquid-cooling elements (e.g., heat exchangers 60 and 64) disposed with in an electronic device.

Further, where desired, sensors 74, such as a flow meter, temperature sensor, and so on, may be installed on or inside one or more of the conduits 58, 62, 66, and 68. The sensors 74 may be used, for example, to determine if there is a problem in the coolant system. For instance, a change in coolant temperature or coolant flow rate may be a sign of a coolant leak, restricted flow, or equipment failure in the coolant circuit. In the illustrated embodiment, the sensors 74 couple to an integrated circuit 76 via wires 78. Furthermore, the integrated circuit 76 may communicate with another component of the electronic device via connector 80 (e.g., card edge connector). In other words, the connector 80 may mate with an expansion connector (e.g., connector 10 of FIG. 1) disposed on a printed circuit board, motherboard, backplane, etc. Lastly, it should be noted that a variety of techniques may be employed to detect and/or mitigate leaks of coolant from the cooling system. For example, a liquid absorbing material or capturing receptacle may be disposed around the conduits and other equipment in the coolant circuit to absorb or capture leaks. Moreover, these liquid absorbing or capturing mechanisms may include conductivity sensors, for example, to detect the presence of leaked coolant (e.g., water). In certain embodiments, the conductivity sensors, if employed, are in electronic communication with circuitry such as the integrated circuit 76 disposed on the expansion cardboard 52.

FIG. 6 is a perspective view of an expansion card 90 having a board 92, a faceplate 94, and liquid cooling components adapted to facilitate the self-contained liquid cooling of an electronic component in an electronic device. The expansion card 90 may fit into an access opening of a standard expansion slot, for example, disposed on the electronic device. The faceplate 94 may include coupling elements 96 and 98 to secure the expansion card 90 within the expansion slot or receptacle on the electronic device (e.g., device 2 of FIG. 1).

In the illustrated embodiment, a circulating pump 100 and heat exchanger 102 are mounted on the board 92. Again, an expansion slot of an electronic device may receive the expansion card 90 having mounted cooling system elements to provide for self-contained liquid cooling within the electronic device. In certain embodiments, the circulating pump 100 supplies coolant through a supply conduit 104 to one or more heat exchangers disposed within the electronic device, e.g., heat exchangers 18 of FIGS. 1-3. The pump 100 circulates return coolant through a return conduit 106 from the heat exchangers (e.g. cold plates, micro-channel heat collector, etc.) to the utility heat exchanger 102. Exemplary types of circulating pumps 100 include an electro-kinetic pump, a diaphragm pump, and so on. Exemplary utility heat exchangers 102 include a radiator, cooling coils, shell-and-tube heat exchanger, and other types of heat exchangers. Moreover, a second circulating pump 108, a second supply conduit 110, and a second return conduit 112 may provide for redundant or independent coolant supply and return, such as described above with reference to FIGS. 2 and 3.

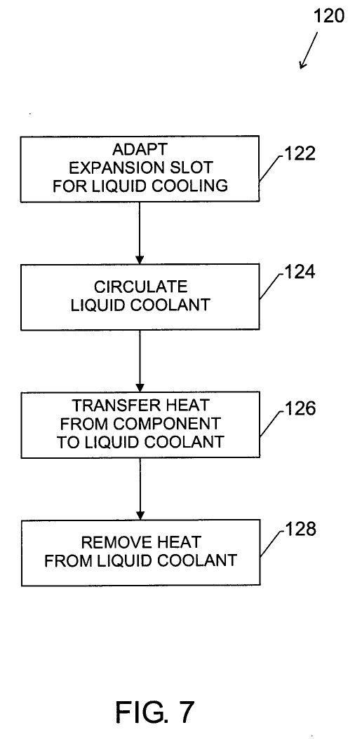

FIG. 7 is a block diagram of a method 120 for cooling an electronic component within an electronic device. An expansion slot and/or expansion card is utilized to facilitate liquid cooling of the component, as referenced in block 122. For example, an adapted faceplate disposed on the receptacle or access opening of expansion slot on the housing of the electronic device may simplify coupling of different parts of liquid cooling systems inside and outside of the housing. Further, elements of the liquid cooling system may mount to a board of an expansion card installed in the expansion slot. In certain embodiments, the cooling system may be self-contained within the electronic device. In operation, whether or not the cooling system is self-contained (within the housing of the electronic device), liquid coolant is transported (e.g., circulated) through a heat exchanger disposed adjacent the electronic component to cool the component (block 124). In operation, heat is transferred from the electronic component to the liquid coolant, as referenced in block 126. For example, the process 120 may dissipate heat from the electronic component into a coolant conduit or passage, which is directly or indirectly coupled to the electronic component via a cold plate, heat exchanger, bracket, and so forth. Further downstream, heat is removed from the liquid coolant in a utility heat exchanger, such as a radiator or cooling coils, to generate a cooled supply of liquid coolant (block 128). The coolant then circulates back to the electronic component to dissipate or draw additional heat from the electronic component.

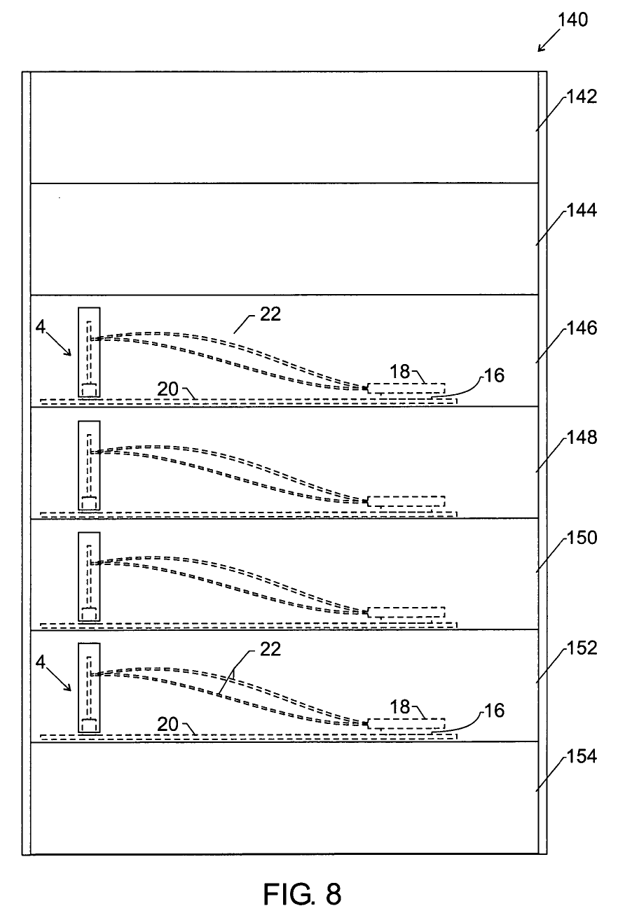

FIG. 8 is a side view of a rack system 140 having a plurality of electronic rack devices 142 through 158, wherein the rack devices 146 through 152 include expansion slots 4 disposed on the housings of the rack devices 146 through 152. The expansion slots 4 facilitate liquid cooling of electronic components 16 within the rack devices. Again, each expansion slot 4 is utilized to route liquid coolant through conduits 22 to heat exchangers 18 mounted over components 16, which may reside on a circuit board 20. To accommodate supply of liquid coolant, the expansion slot 4 may employ a faceplate and/or expansion card, for example. As discussed above, the components 16 to be cooled can include processors, random access memory, hard drives, graphics modules, audio modules, and other electronic devices. In operation, the heat is transferred from the components 16 to the liquid coolant flowing through the illustrated heat exchangers 18 disposed within the rack devices 146, 148, 150, and 152. A utility heat exchanger subsequently removes heat absorbed into the liquid coolant, such that cooler liquid coolant can be returned to the component 16 for further heat withdrawal.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A system for liquid cooling of an electronic device, comprising:
a first heat exchanger configured to mount adjacent an electronic component within a housing of the electronic device, wherein the first heat exchanger is configured to remove heat from the electronic component; and
a support configured to mount in an expansion slot of the electronic device, wherein the support is configured to route liquid coolant to the first heat exchanger.

2. The system of claim 1, wherein the support comprises a plate configured to mount to an access opening through the housing, wherein the plate comprises as least one fitting configured to route a conduit coupled to the first heat exchanger within the housing of the electronic device to a second heat exchanger external to the electronic device.

3. The system of claim 1, wherein the first heat exchanger comprises a water block, a cold plate, a heatpipe, a vapor chamber, a loop thermosiphon, or a microchannel heat collector, or any combination thereof.

4. The system of claim 1, wherein the support comprises an expansion card configured to connect with a card connector of the expansion slot.

5. The system of claim 1, comprising
a liquid return conduit configured to transport the liquid coolant from the first heat exchanger to a second heat exchanger, wherein the second heat exchanger is configured to remove heat from the liquid coolant;
a liquid supply conduit configured to transport the liquid coolant from the second heat exchanger to the first heat exchanger,
wherein at least a portion of the supply conduit or at least a portion of the return conduit, or a combination thereof, is mounted on the support.

6. The system of claim 5, wherein the second heat exchanger is disposed internal to the housing of the electronic device.

7. The system of claim 5, comprising a pumping mechanism disposed on the liquid supply conduit or the liquid return conduit, or a combination thereof.

8. The system of claim 1, comprising a sensor configured to measure a property of the liquid coolant.

9. The system of claim 8, wherein the sensor is communicatively coupled to an integrated circuit disposed on the support.

10. An electronic device, comprising:
a housing;
an expansion slot comprising an access opening in a wall of the housing, a card connector disposed inside the housing, and a region between the access opening and the card connector;
a coolant exchange support mounted in the expansion slot;
a first heat exchanger disposed adjacent an electrical component within the housing; and
a second heat exchanger fluidically coupled to the first heat exchanger via a first conduit and a second conduit; and
a pumping mechanism configured to circulate a liquid coolant between the first and second heat exchangers via the first and second conduits, wherein the first and second conduits are coupled to the coolant exchange support.

11. The system of claim 10, wherein the pumping mechanism is mounted to the coolant exchange support.

12. The system of claim 10, wherein the second heat exchanger is mounted to the coolant exchange support and configured to remove heat from the liquid coolant.

13. The system of claim 10, wherein the coolant exchange support comprises an expansion card coupled to the card connector.

14. The system of claim 10, wherein the electronic device comprises a computer.

15. The system of claim 10, wherein the second heat exchanger is mounted outside and separate from the electronic device

16. A method of liquid cooling of an electronic device, comprising the acts of:
circulating a liquid coolant via an expansion slot of the electronic device; and
transferring heat from an electronic component disposed within the electronic device to the liquid coolant.

17. The method of claim 16, wherein:
the act of circulating comprises the act of circulating the liquid coolant between first and second heat exchangers, wherein the first heat exchanger is mounted adjacent the electronic component; and
the act of transferring heat comprises the act of removing heat from the electronic component through the first heat exchanger to the liquid coolant.

18. The method of claim 17, wherein the act of circulating comprises transporting the liquid coolant between the first heat exchanger and the second heat exchanger disposed inside the electronic device.

19. The method of claim 17, wherein the act of circulating comprises transporting the liquid coolant between the first heat exchanger disposed inside the electronic device and the second heat exchanger disposed outside the electronic device.

20. The method of claim 16, wherein the act of circulating comprises routing the liquid coolant through a conduit coupled to a structure mounted to an opening through a housing of the electronic device.

21. The method of claim 16, wherein the act of circulating comprises routing the liquid coolant through a conduit coupled to an expansion card coupled to a card connector within the expansion slot.

22. The method of claim 16, wherein the act of circulating comprises the act of routing the liquid coolant through a cooling system that is self-contained within a housing of the electronic device.
